(19) United States
(12) Patent Application Publication
(10) Pub. No.: US 2014/0091465 A1
(43) Pub. Date: Apr. 3, 2014

(54) LEADFRAME HAVING SLOPED METAL TERMINALS FOR WIREBONDING

(71) Applicant: TEXAS INSTRUMENTS INCORPORATED, Dallas, TX (US)

(72) Inventors: KAZUNORI HAYATA, HAYAMI-GUN (JP); MASAHIKO GOTO, HAYAMI-GUN (JP); SHOHTA UJIIE, HAYAMI-GUN (JP)

(73) Assignee: TEXAS INSTRUMENTS INCORPORATED, Dallas, TX (US)

(21) Appl. No.: 13/630,494

(22) Filed: Sep. 28, 2012

(51) Int. Cl. H01L 23/495; H01L 23/48; H01L 21/50

(52) U.S. Cl. 257/741; 438/123; 174/536; 257/E21.499; 257/E23.01

(57) ABSTRACT

A method of assembling semiconductor devices includes dispensing a metal paste including metal particles in a solvent onto a bonding area of a plurality of metal terminals of a leadframe. The dispensing provides a varying thickness over the bonding area. The solvent is evaporated to form a sloped metal coating including a first sloped top face and a second sloped top face. The first sloped top face is closer to the die pad compared to the second sloped top face, the second sloped top face increases in coating thickness with decreasing distance to the die pad, and the first sloped top face decreases in coating thickness with decreasing distance to the die pad. A bottom side of semiconductor die including a plurality of top side bond pads is attached to the die pad. Bond wires are connected between the bond pads and the second sloped top faces.

### FIELD

Disclosed embodiments relate to leadframes for integrated circuit (IC) packages, and more particularly, to a leadframe having metal terminals including a metal coating on a base metal.

### BACKGROUND

In the manufacture of semiconductor integrated circuits (ICs), semiconductor IC die (or chips) are mounted on a leadframe, followed by enclosing the IC die and part of the leadframe in a plastic casing to form an IC package. The IC package can be mounted on a printed circuit board (PCB) for interconnection of the electronic devices on the IC die with external circuitry. A leadframe should provide good bondability, molding compound characteristic, and solderability, so that it can facilitate the packaging process. To provide these characteristics, various coatings may be formed on the leadframe surface.

A conventional method for providing improved bondability for the interconnection between bond wires and bonding areas of a leadframe is to plate a metal such as silver (Ag) on the bonding areas including on the metal terminals within the package before wire bonding. Wire bonding is generally performed by a first bonding which forms a ball bond by placing a capillary over the bond pad of the IC die with a ball of the wire extending out of the capillary, and then a second bonding for bonding the ball to the bond pad. The capillary is then moved to a metal terminal (e.g., lead finger) of the lead frame to which a second bond is to be made with the wire travelling with respect to the capillary bore, and a stitch bond is made to the metal terminal (e.g., lead finger) using the capillary with the wire then being broken, leaving a small wire pigtail extending out of the capillary.

After the semiconductor IC is sealed in a plastic casing, in the case of a leaded plastic package, where the terminals comprise leads having internal leads portions which are encapsulated, the external lead portions may be plated with a layer of an alloy of tin/lead (Sn/Pb) to provide suitable solderability for the external lead portions of the IC package to allow ease of mounting on a PCB by soldering. Plating generally provides a smooth and constant thickness metal coating.

### SUMMARY

Disclosed embodiments recognize when the metal coating on bonding areas of metal terminals (e.g., leads or lead fingers) of a leadframe is provided by a metal paste dispensing apparatus such an ink-jet, the surface of the metal coating is significantly rougher as compared to an electroplated metal coating. Such rough/uneven surfaces can cause reduced contact area by the capillary and the bond wire during the second bonding process reducing the applied pressure, and as a result reducing the contact area of the stitch bond between the bond wire and metal terminal, leading to a reduced pull strength of the stitch bond.

Disclosed embodiments also recognize ink-jetting and dispensing have the flexibility to control both the volume dispensed and position. Sloped metal terminal coatings including sloped top faces are provided by controlling the dispensed metal coating volume as a function of position. By controlling the angle of the top metal terminal surface to reduce the angle between the terminal surface and the capillary/bond wire out from the capillary during wire bonding, the contact area of capillary and the bond wire to the top metal terminal surface is increased. As a result, wire bond ability, pull strength, shear strength and break mode, are all improved.

### BRIEF DESCRIPTION OF THE DRAWINGS

Reference will now be made to the accompanying drawings, which are not necessarily drawn to scale, wherein:

FIG. 1 is a flow chart that shows steps in an example method of assembling semiconductor devices including sloped metal coatings on metal terminals of a leadframe, according to an example embodiment.

FIG. 2A is a cross sectional depiction of a disclosed metal terminal of a leadframe having a sloped metal coating for a metal terminal position in the package that receives a bond wire from the right of the FIG. according to an example embodiment, where the sloped metal coating includes a first sloped top face and a second sloped top face angled relative to the first sloped top face.

FIG. 2B is a cross sectional depiction of a disclosed metal terminal of a leadframe having a sloped metal coating for a metal terminal position in the package that receives a bond wire from the left of the FIG. according to an example embodiment, where the sloped metal coating includes a first sloped top face and a second sloped top face angled relative to the first sloped top face.

FIG. 2C depicts one method using an ink-jet to form disclosed metal terminals having a sloped metal coating, according to an example embodiment.

FIG. 3 is cross-sectional view of an encapsulated semiconductor package having a leadframe including sloped metal terminals, according to an example embodiment.

FIG. 4A is a schematic top view of a leadless leadframe including sloped metal terminals, according to an example embodiment.

FIG. 4B is a schematic top view of a leaded leadframe including sloped metal terminals, according to an example embodiment.

FIG. 5 is a plot of pull strength vs. thickness difference across the metal coated surface of metal terminals including disclosed sloped metal terminals.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

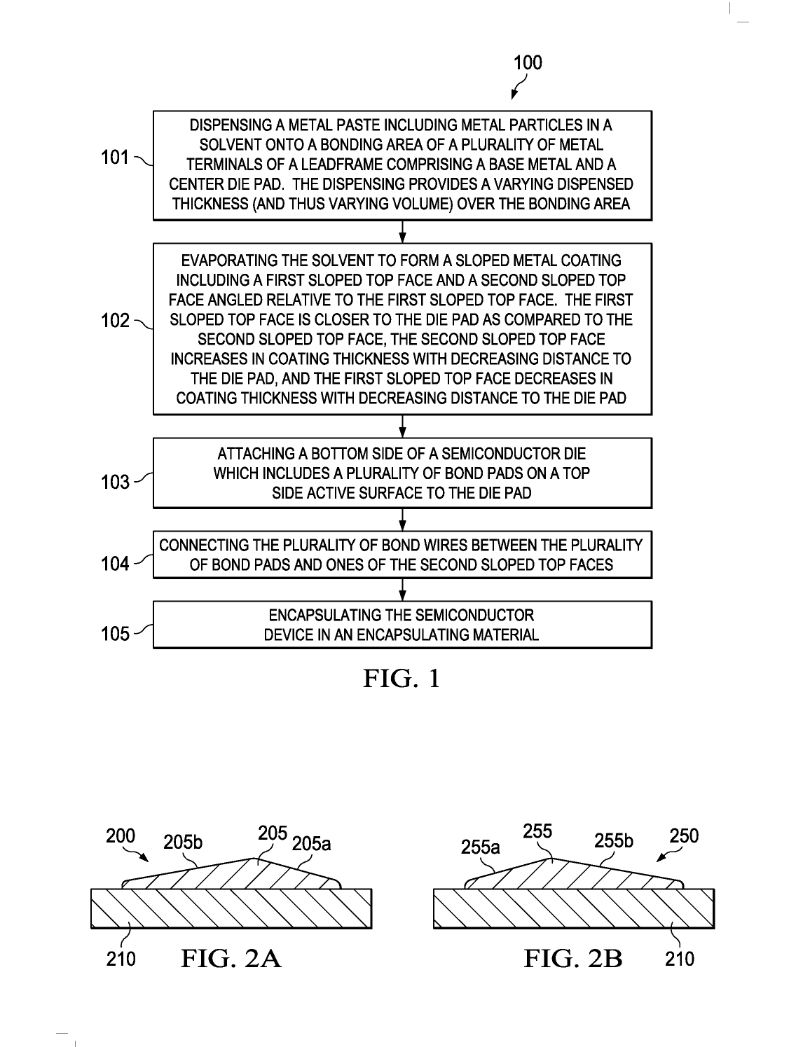

FIG. 1 is a flow chart that shows steps in an example method 100 of assembling semiconductor devices including sloped metal coatings on metal terminals of a leadframe, according to an example embodiment. Disclosed embodiments can be applied to both leadless packages having internal terminals comprising lead fingers and leaded packages where the plurality of metal terminals comprise a plurality of leads (or pins) including an internal lead portion and an external lead portion.

Step 101 comprises dispensing a metal paste including metal particles in a solvent onto a bonding area of a plurality of metal terminals of a leadframe comprising a base metal and a center die pad. The dispensing provides a varying dispensed thickness (and thus varying volume) over the bonding area, with a range in thickness after solvent removal (step 102) of at least 1 μm, typically providing a thickness range between 2 μm and 8 μms. The base metal of the leadframe is generally copper or a copper alloy including Alloy 194, C7025, KCF125, EFTEC, or can be other than copper comprising such as a nickel/ferrite alloy (e.g., Ni-Fe 42 alloy). A typical thickness for the base metal is 0.15 mm to 0.30 mm. The metal particles in the metal paste can comprise metals such as silver, copper, aluminum or gold, or alloys thereof.

A computer controlled ink jet apparatus can be used for the dispensing. Other dispensing apparatus can include computer controlled needle dispensers (air, mechanical) and jet dispensers. These methods all dispense metal particles in a solvent (a metal paste), and can print a paste with high resolution.

In the case of ink-jet printing, the ink-jet printing action can be induced by various technologies known in the art, including piezoelectric or thermal ink jet printers. Ink-jet printing operates via a series of nozzles to shoot small droplets of liquid onto a surface with high precision. The nozzles are part of a print head that can be moved back and forth (e.g., by a stepper motor) with respect to the surface being printed. The surface being printed can also be moved relative to the print head.

Disclosed coatings having sloped (angled) top faces can be achieved by computer control of the dispensed metal coating volume as a function of position. For example, for a constant paste flow rate, slower translations or longer times result in higher thicknesses compared to faster translation/shorter times. Dispensed dot size may also be used to control dispensed thickness and thus dispensed volume.

Step 102 comprises evaporating the solvent to form a sloped metal coating including a first sloped top face and a second sloped top face angled relative to the first sloped top face. The first sloped top face is closer to the die pad as compared to the second sloped top face, the second sloped top face increases in coating thickness with decreasing distance to the die pad, and the first sloped top face decreases in coating thickness with decreasing distance to the die pad. Heat and/or ultraviolet light may be used for evaporating the solvent.

A typical average thickness for the sloped metal coating is from 3 μm to 10 μm, such as around 5 μm in one particular embodiment. As noted above, the thickness difference across the metal coating is typically 2 μm to 8 μm, such as 8 μm as a maximum thickness and 4 μm at a minimum thickness for a 4 μm thickness difference.

Step 103 comprises attaching a bottom side of a semiconductor die which includes a plurality of bond pads on a top side active surface to the die pad. A gluing agent/adhesive, such as a silver filled epoxy may be used for the attachment.

Step 104 comprises connecting the plurality of bond wires between the plurality of bond pads and ones of the second sloped top faces. The bonding connection is generally a direct connection (i.e. no solder needed). In the bonding process, a plurality bond wires, such as gold or aluminum wires, each having one end bonded to one bonding pad (not shown) on the semiconductor die and the other end bonded to the metal coating on the metal terminals (internal leads for a leaded package), are used for the interconnect. Known wire bonding techniques may be used.

Step 105 comprises encapsulating the semiconductor device in an encapsulating material, such as a polymer. An electrically non-conducting (dielectric) encapsulation polymer can be molded over the package in the encapsulation step. The packaged semiconductor device is then generally electrically tested.

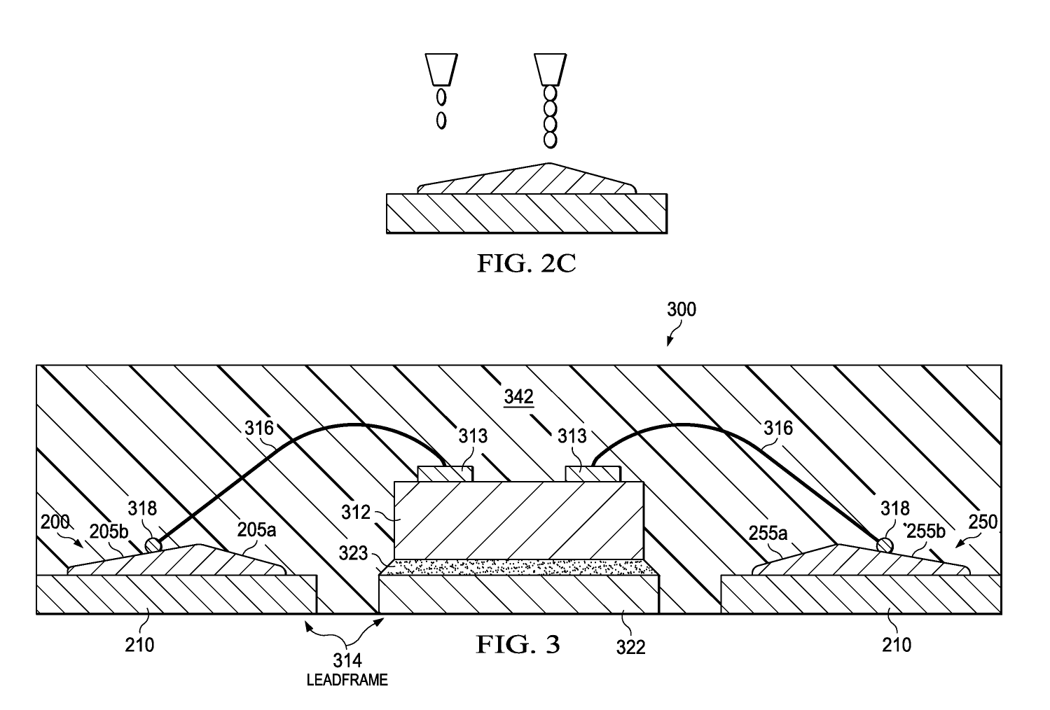

FIG. 2A is a cross sectional depiction of a disclosed metal terminal 200 having a sloped metal terminal coating 205 on a base metal 210 for a position in a packaged semiconductor device that receives a bond wire from the right of the FIG. The sloped metal coating 205 includes a first sloped top face 205a and a second sloped top face 205b angled relative to the first sloped top face 205a. As shown in encapsulated semiconductor package 300 of FIG. 3, the first sloped top face 205a of metal terminal 200 is closer to the die pad 322 compared to the second sloped top face 205b, the second sloped top face 205b increases in coating thickness with decreasing distance to the die pad 322, and the first sloped top face 205a decreases in coating thickness with decreasing distance to the die pad 322.

FIG. 2B is a cross sectional depiction of a disclosed metal terminal 250 having a sloped metal terminal coating 255 on base metal 210 for a position in a packaged semiconductor device that receives a bond wire from the left of the FIG. The sloped metal coating 255 includes a first sloped top face 255a and a second sloped top face 255b angled relative to the first sloped top face 255a. As shown in FIG. 3, the first sloped top face 255a of metal terminal 250 is closer to the die pad 322 compared to the second sloped top face 255b, the second sloped top face 255b increases in coating thickness with decreasing distance to the die pad 322, and the first sloped top face 255a decreases in coating thickness with decreasing distance to the die pad 322.

FIG. 2C depicts an example method using an ink-jet to form disclosed metal terminals having a sloped metal coating, according to an example embodiment. Areas designed to have thicker coatings have the dispensed volume increased. For areas needing thinner coatings, the dispensed volume is reduced, such as by minimizing the dot size to reduce the volume as shown in FIG. 2C.

FIG. 3 is cross-sectional view of an encapsulated semiconductor package 300 having disclosed metal terminals 200, 250 including sloped metal terminal coatings, according to an example embodiment. The semiconductor package 300 includes a semiconductor die 312 having bond pads 313, a leadframe 314, a plurality of bond wires 316, and a plurality of stitch bonds 318. The leadframe 314 includes several metal terminals 200, 250 (leads for a leaded package and lead fingers for a leadless package) and a die pad 322 having a die attach adhesive 323 thereon for supporting the semiconductor die 312. The semiconductor device includes several electrodes connected to the metal terminals 200, 250 by the bond wires 316. An electrically non-conducting encapsulation polymer 342 is molded over the package 300.

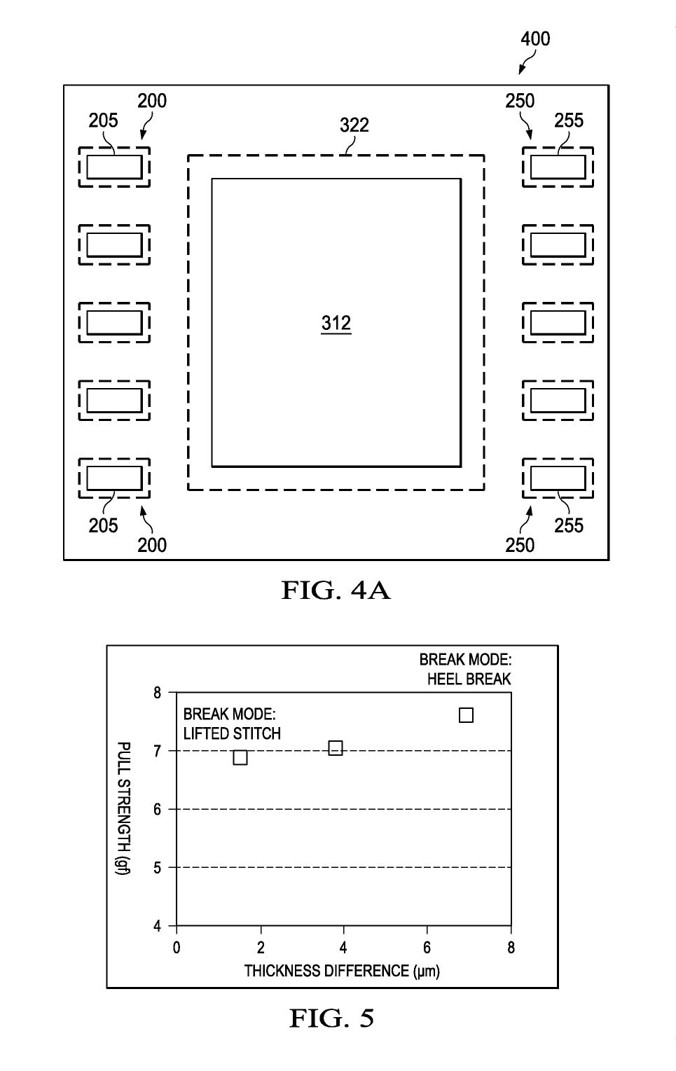

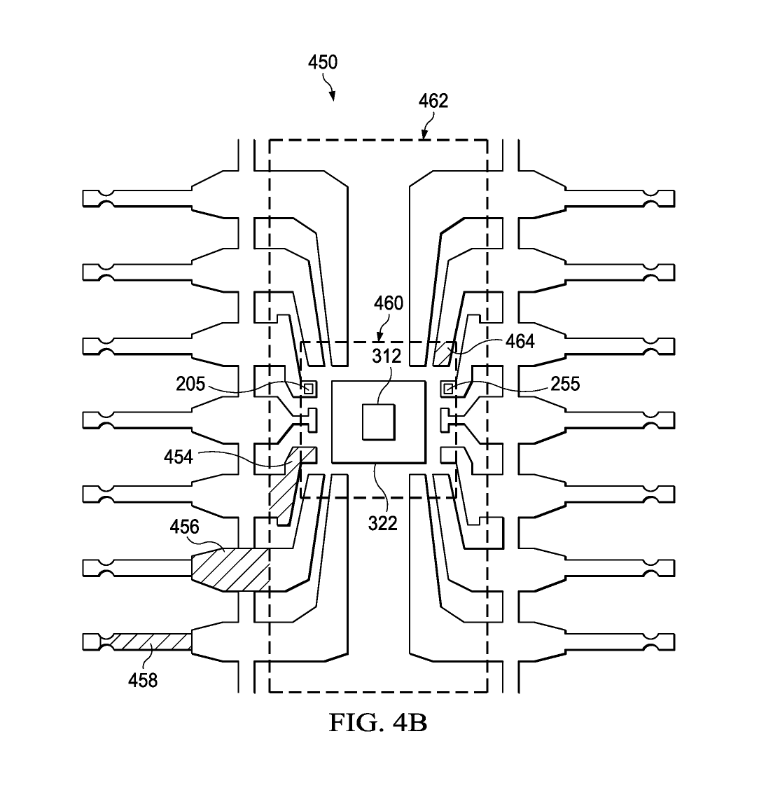

FIG. 4A is a schematic top view of a leadless leadframe 400 shown as a dual-flat no-leads (DFN) leadframe including sloped metal terminals, according to an example embodiment. The leadframe 400 includes metal terminals 200 on the left side of the die pad 322, and metal terminals 250 on the right side of the die pad 322, which are to be connected directly to the semiconductor die 312 mounted on die pad 322.

FIG. 4B is a schematic top view of a leaded leadframe 450 including sloped metal terminals, according to an example embodiment. The leadframe 450 includes a lead portion including a number of internal leads 454 that are to be connected directly to the semiconductor die 312 mounted on die pad 322, a number of corresponding lead shoulders 456 connected to the internal leads 454, and a number of corresponding external leads 458 that are connected to the lead shoulders 456 for connection to external circuitry on a printed circuit board (not shown).

Functionally, the leadframe 450 is divided into a package area, as the area enclosed by a dashed box pointed shown by reference numeral 462, which includes a bonding area (or called a coin area), as the area enclosed by a dashed box pointed out by reference numeral 460, therein and the internal leads 454. The bonding area 460 includes the die pad 322 and the free end (referred to as coin-lead tip) 464 of the internal leads 454. The coin-lead tip 464 of the internal leads 454 is where disclosed sloped metal terminal coatings are provided.

As shown in FIG. 4B, coating 255 (see FIG. 2B) is on a coin-lead tip 464 on the right side of the die pad 322 and coating 205 (see FIG. 2A) is on a coin-lead tip 464 on the left side of the die pad 322. Although not shown, all coin-lead tips 464 can include a disclosed sloped metal terminal coating. The area beyond the package area 462 on the leadframe 450 includes the lead shoulders 456 and the external leads 458.

FIG. 5 is a plot of pull strength vs. thickness difference (in absolute value) across the coated surface of metal terminals including disclosed sloped metal terminals. Different directions of metal coating slopes (metal terminals 200, 250) and magnitudes of pad slopes were prepared on metal terminals by changing ink-jetting volume as a function of position. Pull strength is seen to increase with a larger coating thickness difference (larger pad slope). A 6 gF pull strength was found to be limited by a break mode involving a lifted stitch (from the metal terminal) for conventional metal terminals having planar metal coatings. In contrast, for disclosed metal terminals having a sloped metal coating a nearly 7.8 gF pull strength (a 30% increase over conventional planar metal coatings) is provided which was found to be now limited by a break mode involving a heel break/lift (from the bond pad on the IC die).

Disclosed embodiments can be integrated into a variety of assembly flows to form a variety of different semiconductor IC devices and related products. The assembly can comprise single semiconductor die or multiple semiconductor die, such as PoP configurations comprising a plurality of stacked semiconductor die. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A method of assembling semiconductor devices, comprising:
dispensing a metal paste including metal particles in a solvent onto a bonding area of a plurality of metal terminals of a leadframe including a base metal, said leadframe having a center die pad, wherein said dispensing provides a varying dispensed thickness over said bonding area;
evaporating said solvent to form a sloped metal coating including a first sloped top face and a second sloped top face angled relative to said first sloped top face;
said first sloped top face being closer to said die pad compared to said second sloped top face,
said second sloped top face increasing in coating thickness with decreasing distance to said die pad, and said first sloped top face decreasing in coating thickness with decreasing distance to said die pad;
attaching a bottom side of semiconductor die including a plurality of bond pads on a top side active surface to said die pad, and
connecting a plurality of bond wires between said plurality of bond pads and respective ones of said second sloped top faces.

2. The method of claim 1, wherein said second sloped top face has a larger area compared to an area of said first sloped top face.

3. The method of claim 1, wherein said plurality of bond wires are directly connected to respective ones of said second sloped top faces.

4. The method of claim 1, wherein said sloped metal coating comprises silver, copper, aluminum or gold, or alloys thereof.

5. The leadframe of claim 1, wherein a thickness difference across said sloped metal coating is 2 μm to 8 μm.

6. The leadframe of claim 1, wherein said dispensing comprises computer controlled ink-jet dispensing.

7. A leadframe, comprising:
a die pad for attaching a semiconductor die, said semiconductor die including a top side active surface having a plurality of bond pads thereon;
a plurality of metal terminals outside said die pad, wherein said plurality of metal terminals include a base metal and a sloped metal coating thereon,
wherein said sloped metal coating includes:
a first sloped top face and a second sloped top face angled relative to said first sloped top face;
said first sloped top face being closer to said die pad compared to said second sloped top face,
said second sloped top face increasing in coating thickness with decreasing distance to said die pad, and said first sloped top face decreasing in coating thickness with decreasing distance to said die pad.

8. The leadframe of claim 7, wherein said second sloped top face has a larger area compared to an area of said first sloped top face.

9. The leadframe of claim 7, wherein said sloped metal coating comprises silver, copper, aluminum or gold, or alloys thereof.

10. The leadframe of claim 7, wherein a thickness difference across said sloped metal coating is 2 μm to 8 μm.

11. A semiconductor device assembly, comprising:
a die pad on which a semiconductor die including a top side active surface having a plurality of bond pads thereon is attached;
a plurality of metal terminals outside said die pad, wherein said plurality of metal terminals include a base metal and a sloped metal coating thereon,
wherein said sloped metal coating includes:
a first sloped top face and a second sloped top face angled relative to said first sloped top face;
said first sloped top face being closer to said die pad compared to said second sloped top face,
said second sloped top face increasing in coating thickness with decreasing distance to said die pad, and said first sloped top face decreasing in coating thickness with decreasing distance to said die pad, and
bond wires connecting between said plurality of bond pads and directly to respective ones of said second sloped top faces.

12. The semiconductor device assembly of claim 11, wherein said second sloped top face has a larger area compared to an area of said first sloped top face.

13. The semiconductor device assembly of claim 11, wherein said sloped metal coating comprises silver, copper, aluminum or gold, or alloys thereof.

14. The semiconductor device assembly of claim 11, wherein a thickness difference across said sloped metal coating is 2 μm to 8 μm.

15. The semiconductor device assembly of claim 11, wherein said bond wires are directly connected to respective ones of said second sloped top faces.
